(19) United States
(12) Patent Application Publication
(10) Pub. No.: US 2006/0291281 A1
(43) Pub. Date: Dec. 28, 2006

(54) NON-VOLATILE MEMORY, MANUFACTURING AND OPERATING METHOD THEREOF

(76) Inventors: Pin-Yao Wang, Hsinchu City (TW); Liang-Chuan Lai, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,969

(22) Filed: Dec. 13, 2005

(30) Foreign Application Priority Data
Jun. 27, 2005 (TW) 94121372

(51) Int. Cl. G11C 11/34

(52) U.S. Cl. 365/185.05

(57) ABSTRACT

A non-volatile memory having a substrate, a select gate, a pair of charge storage layers, a pair of source/drain regions and a control gate is provided. At least a pair of trenches are formed in the substrate. The select gate is formed on the substrate between the pair of trenches. A pair of charge storage layers is formed on the sidewalls of the trenches next to the select gate. A pair of source/drain regions is formed in the substrate at the bottom of the trenches. The control gate is formed on the substrate to fill the trenches completely.

### CROSS-REFERENCE TO RELATED APPLICATION

This application claims the priority benefit of Taiwan application serial no. 94121372, filed on Jun. 27, 2005. All disclosure of the Taiwan application is incorporated herein by reference.

### BACKGROUND OF THE INVENTION

### Field of the Invention

The present invention relates to a semiconductor device. More particularly, the present invention relates to a non-volatile memory, manufacturing and operating method thereof.

### Description of the Related Art

Among various types of non-volatile memory products, electrically erasable programmable read only memory (EEPROM) is a memory device that has been widely used in personal computers and electronic equipment. Data can be stored, read out or erased from the EEPROM many times and stored data are retained even after power supplying the devices is cut off.

Typical EEPROM includes a floating gate and a control gate fabricated by doped polysilicon. Furthermore, the floating gate is isolated from the control gate by a dielectric layer and the floating gate is isolated from the substrate by a tunneling oxide layer. When a flash memory performs a data write/erase operation, a biased voltage is applied to the control gate and the source/drain region so that electrons can be injected into or pulled out from the floating gate. An operating voltage is applied to the control gate when data in the flash memory are read. At this moment, the charging state of the floating gate will directly affect the turn on/turnoff of the channel underneath. In fact, the logical read-out value, a data value of ‘0’ or of ‘1’, is based on the turn-on or turn-off of the channel.

Because it is difficult to control the quantity of electrons pulled out from the floating gate when the aforementioned EEPROM undergoes a data erasing operation, an excessive number of electrons may be expelled from the floating gate, which leads to the presence of a net positive charge. This phenomenon is referred to as over-erase. When the over-erasing phenomenon is severe, the channel underneath the floating gate may remain conductive before an operating voltage to the control gate is provided. As a result, data read-out errors may occur.

To resolve the over-erase problem in the memory device, a split gate design is widely adopted by many types of EEPROM. One of the structural features of the design, aside from a control gate and a floating gate, is a select gate (or the erase gate) disposed on the sidewalls of the control gate and the floating gate above the substrate. Another inter-gate dielectric layer isolates the select gate from the control gate and isolates the floating gate from the substrate. Hence, when the over-erase phenomenon is exceptionally serious (the channel underneath the floating gate remains conductive before an operation voltage in the control gate is provided), the channel underneath the select gate can still be in a turnoff state. In other words, the turnoff of the select gate will lead to a non-conductive state between the drain region and the source region so that data read-out errors can be prevented.

However, the split-gate structure requires a larger area to accommodate the additional split gate so that each memory cell will have a larger dimension. Consequently, each memory cell will have a size greater than a conventional stacked-type memory cell, and it will be difficult to achieve a high level of integration. With the ever-increasing demand for highly integrated circuits, a means of producing small-sized, high-quality, and highly-integrated memory devices is a common goal in the semiconductor fabrication industry.

### SUMMARY OF THE INVENTION

Accordingly, at least one objective of the present invention is to provide a non-volatile memory, manufacturing and operating method thereof capable of storing two bits of data in each memory cell unit so that the level of integration of the devices can be raised.

At least a second objective of the present invention is to provide a non-volatile memory, manufacturing and operating method thereof capable of programming efficiently and increasing the operating speed of the devices.

At least a third objective of the present invention is to provide a non-volatile memory and manufacturing and operating method thereof having a simpler fabrication process for reducing the production cost.

To achieve these advantages and to satisfy the purpose of the invention, as embodied and broadly described herein, the invention provides a non-volatile memory including a substrate, a select gate, a pair of charge storage layers, a pair of source/drain regions and a control gate. At least a pair of trenches are formed in the substrate. The select gate is formed on the substrate between the pair of trenches. The pair of charge storage layers are formed on the respective sidewalls of the trenches next to the select gate. The pair of source/drain regions are formed in the substrate at the bottom of the trenches. The control gate is formed on the substrate to fill the trenches completely.

In the aforementioned non-volatile memory, its two charge storage layers are fabricated using doped polysilicon or silicon nitride. There is a sharp corner between the two charge storage layers and the select gate. Furthermore, there is a tunneling dielectric layer disposed between the two charge storage layers and the substrate and there is an inter-gate dielectric layer disposed between the two charge storage layers and the control gates. The select gate is fabricated using doped polysilicon. There is also a select gate dielectric layer disposed between the select gate and the substrate.

The present invention also provides an alternative non-volatile memory. The non-volatile memory includes a substrate, a plurality of select gates, a plurality of charge storage layers, a plurality of bit lines, and a plurality of word lines. The substrate has a plurality of trenches formed therein. These trenches extend in a first direction. The select gates are formed on the substrate between every pair of two adjacent trenches. The select gates extend in the first direction as well. The charge storage layers are formed on respective sidewalls of the respective trenches. The bit lines are formed in the substrate at the bottom of the trenches. The word lines are formed in parallel to one another on the substrate to fill the respective trenches. These word lines extend in a second direction such that the second direction and the first direction cross over each other.

In the aforementioned non-volatile memory, the charge storage layers are fabricated using doped polysilicon or silicon nitride. There is a sharp corner between the charge storage layers and the select gate. There is a tunneling dielectric layer between each charge storage layer and the substrate and there is an inter-gate dielectric layer between each charge storage layer and its corresponding word line.

In the aforementioned non-volatile memory, an anti-punch-through doped region is disposed in the substrate between every pair of adjacent word lines. There is a select gate dielectric layer disposed between each select gate and the substrate. Furthermore, the charge storage layers on the sidewalls of the trenches are isolated from one another.

Since there is no gap between the memory cells in the non-volatile memory of the present invention, overall level of integration of the memory devices can be raised. Furthermore, the two charge storage layers on separate sidewalls of each trench next to the select gate are respectively capable of storing a single bit of data. In other words, a single memory cell in the non-volatile memory of the present invention can hold two bits of data. Moreover, by controlling the depth of the trench, the channel length of the memory cell can be controlled to prevent any abnormal electrical punch-through in the memory cell.

The present invention also provides a method of manufacturing a non-volatile memory. First, a substrate is provided. Then, a plurality of first conductive layers are formed over the substrate and extending in a first direction. Thereafter, using the first conductive layer as a mask, a portion of the substrate is removed to form a plurality of trenches in the substrate. A first dielectric layer is formed over the substrate and then a first charge storage layer and a second charge storage layer are formed on respective sidewalls of the trenches. After that, a plurality of doped regions are formed in the substrate at the bottom of the trenches and then a second dielectric layer is formed over the substrate. Then, a plurality of second conductive layers are formed over the substrate and extending in a second direction. These second conductive layers completely fill the trenches and the second direction and the first direction cross over each other.

In the aforementioned method of fabricating the non-volatile memory, the method of forming the first charge storage layer and the second charge storage layer on the respective sidewalls of the trenches includes the following steps. First, the charge storage material is deposited into the trenches to form a charge storage material layer. Then, the charge storage material layer is etched until the top portion of the charge storage material layer is below the upper surface of the substrate. Thereafter, spacers are formed on respective sidewalls of the trenches to cover a portion of the charge storage material layer. After that, using the spacers and the first conductive layer as a mask, a portion of the charge storage material layer is removed to form the first charge storage layer and the second charge storage layer on respective sidewalls of the trenches.

In the aforementioned method of fabricating the non-volatile memory, the method of forming the first charge storage layer and the second charge storage layer on respective sidewalls of the trenches includes the following steps. First, charge storage material is deposited into the trenches. Then, the charge storage material layer is patterned to form the first charge storage layer and the second charge storage layer on the sidewalls of the trenches.

In the aforementioned method of fabricating the non-volatile memory, the method of forming the first conductive layer over the substrate includes forming a gate dielectric layer over the substrate and then forming a conductive material layer over the gate dielectric layer. After a cap layer is formed over the conductive material layer, pattern the cap layer, the conductive material layer and the gate dielectric layer.

In the aforementioned method of fabricating the non-volatile memory, the first charge storage layer and the second charge storage layer are fabricated using doped polysilicon or silicon nitride.

As for the method of fabricating the non-volatile memory in the present invention, because the charge storage layers (the floating gates) and the control gates are formed in the trenches of the substrate, the dimension of each memory cell can be reduced. Hence, the level of integration of the devices can be raised. Moreover, the charge storage layer (the two charge storage layers next to the first conductive layer) on the sidewalls of the trenches is able to respectively store one bit of data. In other words, each memory cell in the non-volatile memory of the present invention is able to hold two bits of data. Furthermore, by controlling the depth of the trench, the channel length of the memory cell can be controlled as well to prevent any abnormal electrical punch-through in the memory cell. In addition, the process of manufacturing the non-volatile memory in the present invention is very much simplified so that a higher level of integration for a memory cell array can be achieved.

The present invention also provides a method for operating a non-volatile memory with the aforementioned memory cell array structure. The memory cell array includes a plurality of select gates disposed on the substrate and a trench disposed in the substrate between every pair of adjacent select gates, a plurality of charge storage layers disposed on respective sidewalls of the trenches next to the select gate, a plurality of control gates filling the trenches between two adjacent select gates, a plurality of word lines aligned in parallel in the row direction and connected to the control gate in the same row, a plurality of select gate lines aligned in the column direction and connected to the select gate in the same column, and a plurality of bit lines aligned in parallel in the column direction and disposed in the substrate under the trench. The two adjacent control gates in the row direction, the select gate between two adjacent control gates and the two charge storage layers adjacent to the select gate together form a memory cell. In each memory cell, the charge storage layer on the first side of the select gate constitutes a first bit of the memory cell, and the charge storage layer on the second side of the select gate constitutes a second bit of the memory cell. The method of programming the non-volatile memory includes applying a first voltage to the selected word line connected to the selected memory cell, applying a second voltage to the first selected bit line on the first bit side of the selected memory cell, applying a third voltage to the second selected bit line on the second bit side of the selected memory cell, and applying a fourth voltage to the selected select gate line of the selected memory cell. The fourth voltage is close to the threshold voltage of the select gate, the second voltage is greater than the third voltage, and the first voltage is greater than the second voltage so that a first bit of the selected memory cell can be programmed through the source side injection effect.

In the aforementioned method of operating the non-volatile memory, the first voltage is about 8V, the second voltage is about 5V, the third voltage is about 0V, and the fourth voltage is about 2V.

The aforementioned method of operating the non-volatile memory further includes applying a first voltage to the selected word line which connects with the selected memory cell, applying a third voltage to the first selected bit line on the first bit side of the selected memory cell, applying a second voltage to the second selected bit line on the second bit side of the selected memory cell, and applying a fourth voltage to the selected select gate line of the selected memory cell during the programming operation. The fourth voltage is close to the threshold voltage of the select gate, the second voltage is greater than the third voltage, the first voltage is greater than the second voltage, so that the second bit of the selected memory cell can be programmed through the source side injection effect.

In the aforementioned method of operating the non-volatile memory, the first voltage is about 8V, the second voltage is about 5V, the third voltage is about 0V, and the fourth voltage is about 2V.

The aforementioned method of operating the non-volatile memory further includes applying a fifth voltage to the non-selected select gate line so that the channel underneath the non-selected select gate is blocked during the programming operation. The fifth voltage is about −1V.

In the aforementioned method of operating the non-volatile memory, the erasing process includes applying a sixth voltage to the word line and applying a seventh voltage to the substrate so that the electrons stored in the charge storage layer are channeled into the word line. The voltage differential between the sixth voltage and the seventh voltage will initiate a Fowler-Nordheim (FN) tunneling effect.

In the aforementioned method of operating the non-volatile memory, the voltage differential is about 12V-20V. The sixth voltage is about 15V and the seventh voltage is about 0V.

In the aforementioned method of operating the non-volatile memory, the sixth voltage is about 10V and the seventh voltage is about −5V.

In the aforementioned method of operating the non-volatile memory, the erasing process includes applying an eighth voltage to the select gate line and applying a ninth voltage to the substrate so that the electrons stored in the charge storage layer are channeled into the select gate line. The voltage differential between the eighth voltage and the ninth voltage will initiate an FN tunneling effect.

In the aforementioned method of operating the non-volatile memory, the voltage differential is about 12V-20V. The eighth voltage is about 15V and the ninth voltage is about 0V.

In the aforementioned method of operating the non-volatile memory, the reading process includes applying a tenth voltage to the selected word line connected to the selected memory cell, applying an eleventh voltage to the first selected word line on the first bit side of the selected memory cell, applying a twelfth voltage to the second selected word line on the second bit side of the selected memory cell, and applying a thirteenth voltage to the selected select gate line of the selected memory cell to read a first bit of data. The eleventh voltage is greater than the twelfth voltage and the tenth voltage is greater than the threshold voltage of the memory cell with no electrons stored but is smaller than the threshold voltage of the memory cell with electrons stored.

In the aforementioned method of operating the non-volatile memory, the tenth voltage is about 7V, the eleventh voltage is about 1.5V, the twelfth voltage is about 0V, and the thirteenth voltage is about 4V.

In the aforementioned method of operating the non-volatile memory, the reading process includes applying a tenth voltage to the selected word line connected to the selected memory cell, applying a twelfth voltage to the first selected bit line on the first bit side of the selected memory cell, applying an eleventh voltage to the second selected bit line on the second bit side of the selected memory cell, and applying a thirteenth voltage to the selected select gate line of the selected memory cell to read a second bit of data. The eleventh voltage is greater than the twelfth voltage. The tenth voltage is greater than the threshold voltage of the memory cell with no electrons stored but is smaller than the threshold voltage of the memory cell with electrons stored.

In the aforementioned method of operating the non-volatile memory, the tenth voltage is about 5V-7V, the eleventh voltage is about 1.5V, the twelfth voltage is about 0V, and the thirteenth voltage is about 4V.

In the method of operating a non-volatile memory according to the present invention, the programming operation is carried out in a source-side injection (SSI) process, utilizing a single bit of data in a single memory cell as an unit. Additionally, the memory cell erasing operation is carried out through the FN tunneling effect. Therefore, the memory cell current can be reduced while the operating speed is increased thanks to the high efficiency of electron injection. As a result, overall current loss is minimized and the power consumption of the chip can be significantly reduced.

The above and other features of the present invention will be better understood from the following detailed description of the preferred embodiments of the invention which is provided in communication with the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a non-volatile memory according to one embodiment of the present invention.

FIG. 1B is a schematic cross-sectional view along line A-A′ of FIG. 1A.

FIG. 1C is a schematic cross-sectional view along line B-B′ of FIG. 1A.

FIG. 2 is a simplified circuit of a memory cell array according to one embodiment of the present invention.

FIG. 3A is a schematic cross-sectional view of a non-volatile memory showing the means of programming the non-volatile memory according to the present invention.

FIG. 3B is a schematic cross-sectional view of a non-volatile memory showing another means of programming the non-volatile memory according to the present invention.

FIG. 3C is a schematic cross-sectional view of a non-volatile memory showing a means of reading data from the non-volatile memory according to the present invention.

FIG. 3D is a schematic cross-sectional view of a non-volatile memory showing another means of reading data from the non-volatile memory according to the present invention.

FIG. 3E is a schematic cross-sectional view of a non-volatile memory showing a means of erasing data from the non-volatile memory according to the present invention.

FIG. 3F is a schematic cross-sectional view of a non-volatile memory showing another means of erasing data from the non-volatile memory according to the present invention.

FIGS. 4A through 4E are schematic cross-sectional views showing the steps for fabricating a non-volatile memory according to one embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and in the description to refer to the same or similar parts.

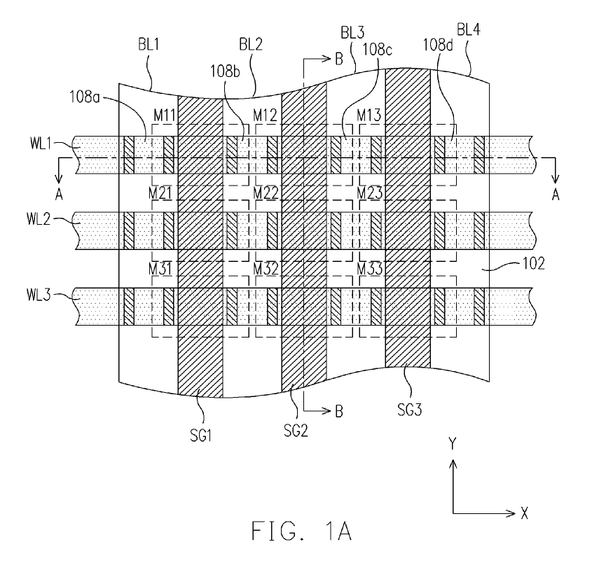

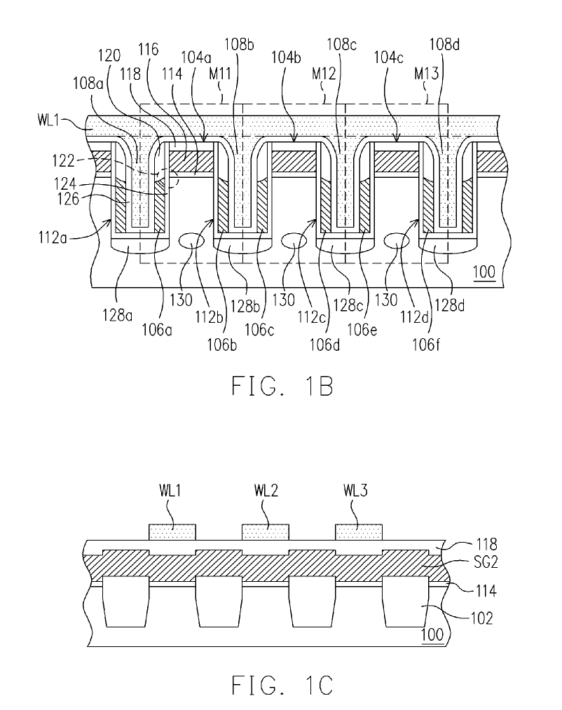

FIG. 1A is a top view of a non-volatile memory according to one embodiment of the present invention. FIG. 1B is a schematic cross-sectional view along line A-A′ of FIG. 1A. FIG. 1C is a schematic cross-sectional view along line B-B′ of FIG. 1A.

As shown in FIG. 1A, the non-volatile memory array in the present invention includes a substrate 100, a plurality of memory cells M11˜M33, a plurality of word lines WL1˜WL3, a plurality of select gate lines SG1˜SG3, and a plurality of bit lines BL1˜BL4.

The substrate 100 is a silicon substrate, for example. The substrate 100 has a plurality of embedded device isolation structures 102 to define active regions. The device isolation structures 102 are aligned in parallel to one another and extend in a direction X.

The memory cells M11˜M33 are formed on the substrate 100 and aligned in a row/column configuration. The word lines WL1˜WL3 are connected to the control gates in the same row of memory cells. The word lines WL˜WL3 are aligned in parallel to one another and extend in the X direction, for example. The select gate lines SG1˜SG3 are connected to the select gates in the same column of memory cells. The select gate lines SG1˜SG3 are aligned in parallel to one another and extend in an Y direction, for example. The X and the Y directions cross over each other. The bit lines BL1˜BL4 are connected to the source/drain regions of the memory cells in the same column. The bit lines BL1˜BL4 are aligned in parallel to one another and extend in the Y direction, for example. Furthermore, every pair of neighboring memory cells uses a single bit line (source/drain region).

The structure of the non-volatile memory in the present invention is further explained in more detail. Here, only the memory cells M11˜M13 which are connected together through the word line WL1 are used as an example.

As shown in FIGS. 1A, 1B, and 1C, the non-volatile memory structure mainly includes a substrate 100, a plurality of select gate structures 104a˜104c, a plurality of charge storage structures 106a˜106f, and a plurality of control gates 108a˜108e.

The substrate 100 is a silicon substrate, for example. A p-type well is also formed in the substrate 100. Furthermore, a plurality of trenches 112a˜112d are formed in the substrate 100. These trenches 112a˜112d are aligned in parallel to one another and extend in the Y direction.

The select gate structures 104a˜104c are formed on the substrate 100 between pairs of adjacent trenches 112a˜112d, for example. Each of the select gate structures 104a˜104c includes a select gate dielectric layer 114, a select gate 116, a cap layer 118 and spacers 120. The select gate dielectric layer 114 is disposed between the select gate 116 and the substrate 100, for example. The select gate dielectric layer 114 is fabricated using silicon oxide, for example. The select gate 116 is fabricated using doped polysilicon, for example. The cap layer 118 is disposed on the top of the select gate 116 and fabricated using an insulating material such as silicon oxide or silicon nitride. The spacers 120 are set up on the sidewalls of the select gate 116. The spacers 120 are fabricated using an insulating material such as silicon oxide or silicon nitride. The select gate lines SG1˜SG3 are connected to the select gate 116 of the memory cells in the same column.

The charge storage layers 106a˜106f are disposed on respective sidewalls of the trenches 112a˜112d, for example. The charge storage layers 106a˜106f are fabricated using a material capable of storing electric charges such as a conductive material (for example, doped polysilicon) or a charge-trapping material (for example, silicon nitride). When the charge storage layers 106a˜106f are fabricated using doped polysilicon, the charge-storage layers 106a˜106f serve as floating gates. As shown in FIG. 1B, the charge storage layers 106a˜106f may have a sharp corner 122 optionally disposed in the area close to the select gate structures 104a˜104c. The sharp corner 122 serves to enhance the erasing operation of the memory cells. A tunneling dielectric layer 124 is also formed between the charge storage layers 106a˜106f and the substrate 100. The tunneling dielectric layer 124 is fabricated using silicon oxide, for example.

The control gates 108a˜108d are set up on the substrate 100 and fill up the trenches 112a˜112d (as shown in FIG. 1B) between pairs of adjacent select gate structures 104a˜104c. The control gates 108a˜108d are serially connected together through the word line WL1. The control gates 108a˜108d and the word line WL1 are formed as a whole, for example. In other words, the control gates 108a˜108d extend into an area above the select gate structures 104a˜104c and connect with one another to form the word line WL1. The control gates 108a˜108d (the word line WL1) are fabricated using a conductive material such as doped polysilicon. An inter-gate dielectric layer 126 is also formed between each charge storage layer 106a˜106d and each control gate 108a˜108d. The inter-gate dielectric layer 126 is fabricated using an insulating material and may include just a single layer or a composite stack such as a silicon oxide layer, an oxide/nitride layer, or an oxide/nitride/oxide layer.

The doped regions 128a˜128d (the source/drain regions) are disposed in the substrate 100 at the bottom of respective trenches 112a˜112d, for example. These doped regions 128a˜128d (the source/drain regions) extend in the Y direction (shown in FIG. 1A) to form the bit lines BL1˜BL4. An anti-punch-through doped region 130 is also formed in the substrate 100 between pairs of adjacent bit lines BL1˜BL4. The anti-punch-through doped regions 130 can prevent an abnormal electrical punch-through between every pair of adjacent bit lines BL1˜BL4.

As shown in FIG. 1B, the two adjacent control gates 108a˜108d, the select gate structures 104a˜104c between every pair of adjacent control gates 108a˜108d, the two charge storage layers 106a˜106f next to the select gate structures 104a˜104c, and the doped regions 128a˜128d (the source/drain regions) adjacent to the two charge storage layers 106a˜106f together form a plurality of memory cells M11˜M13.

For example, the control gate 108a, the control gate 108b, the select gate structure 104a and the two charge storage layers 106a˜106b adjacent to the select gate structure 104a, and the doped regions 128a˜128b (the source/drain regions) adjacent to the two charge storage layers 106a˜106b together form the memory cell M11; the control gate 108b, the control gate 108c, the select gate structure 104b and the two charge storage layers 106c˜106d adjacent to the select gate structure 104a, and the doped regions 128b˜128c (the source/drain regions) adjacent to the two charge storage layers 106c˜106d together form the memory cell M12; the control gate 108c, the control gate 108d, the select gate structure 104c and the two charge storage layers 106e˜106f adjacent to the select gate structure 104c, and the doped regions 128c˜128d (the source/drain regions) adjacent to the two charge storage layers 106a˜106e together form the memory cell M13. The memory cells M11˜M13 are serially connected together in the X direction (the row direction) without any gaps. Furthermore, adjacent memory cells M11˜M13 use the common control gates 108b˜108c and the doped regions 128b˜128c (the source/drain regions) (the bit lines BL2˜BL3). For example, the memory cell M12 and the memory cell M11 use the same control gate 108b and the same doped region 128b (the source/drain region) (the bit line BL2); the memory cell M13 and the memory cell M12 use the same control gate 108c and the same doped region 128c (the source/drain region) (the bit line BL3).

The charge storage layers 106a˜106e of the memory cells M11˜M13 are each capable of storing a single bit of data. Using the memory cell M11 as an example, the charge storage layer 106a (a left bit) on the left side of the select gate structure 104a is able to store one bit of data. The charge storage layer 106b (a right bit) on the right side of the select gate structure 104a is able to store another bit of data. Similarly, each of the memory cells M12˜M13 has two charge storage layers (a left bit and a right bit). In other words, each memory cell of the non-volatile memory in the present invention can hold two bits of data. Since the memory cells M21˜M33 that are serially connected through the word lines WL2˜WL3 have an identical structure to the serially connected memory cells M11˜M13, a detailed description of these structures is not repeated.

In the aforementioned non-volatile memory, there are no gaps among the memory cells M11˜M13 so that the level of integration of the memory cell array can be raised. Furthermore, each of the charge storage layers 106a˜106e (the two charge storage layers next to the select gate structure) on the respective sides of the trenches 112a˜112d can store a single bit of data. In other words, each memory cell in the non-volatile memory of the present invention can store two bits of data. In addition, by controlling the depth of the trenches 112a˜112e, the length of the channel in each memory cell can be adjusted to prevent abnormal electrical-punch-through in the memory cell.

In the aforementioned embodiment, three memory cells M11˜M13 are serially connected together. Obviously, the number of memory cells serially connected together may suitably vary according to the actual need. For example, the same word line may serially connect 32 to 64 memory cells altogether.

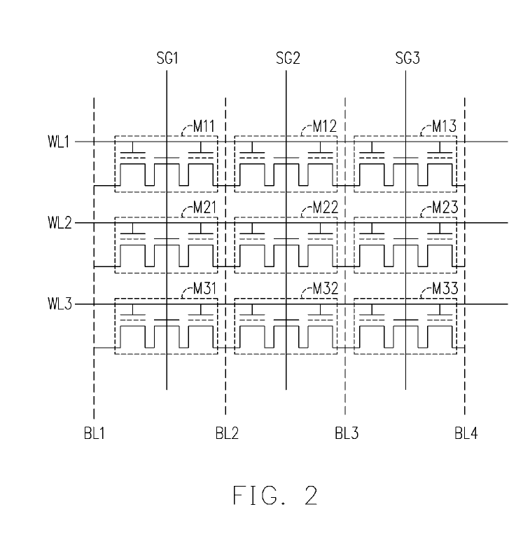

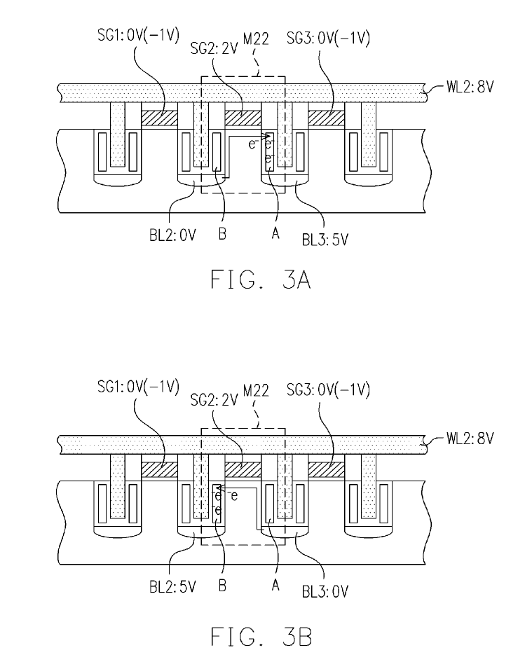

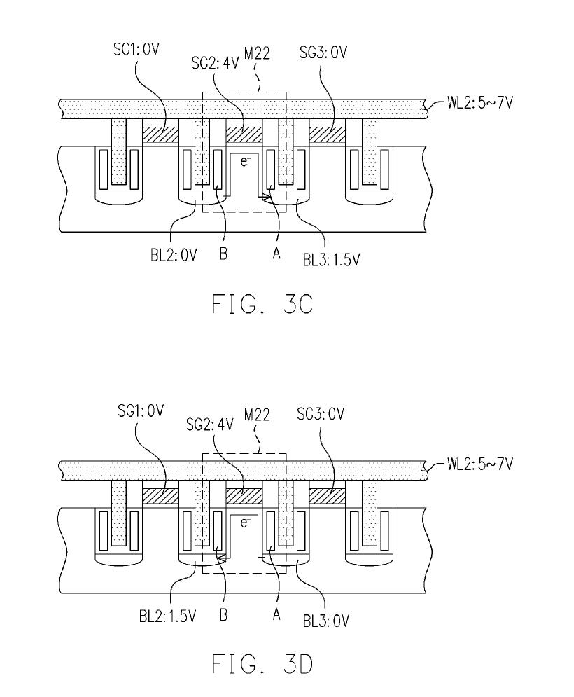

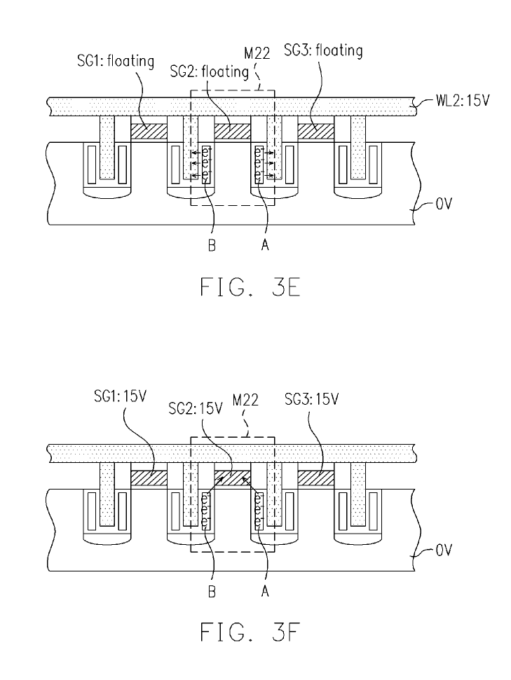

FIG. 2 is a simplified circuit of a memory cell array according to one embodiment of the present invention. Here, a memory cell array including nine memory cells is used as an example to illustrate the operating mode of the memory cell array in the present invention. FIG. 3A is a schematic cross-sectional view of a non-volatile memory showing a means of programming the non-volatile memory according to the present invention. FIG. 3B is a schematic cross-sectional view of a non-volatile memory showing another means of programming the non-volatile memory according to the present invention. FIG. 3C is a schematic cross-sectional view of a non-volatile memory showing a means of reading data from the non-volatile memory according to the present invention. FIG. 3D is a schematic cross-sectional view of a non-volatile memory showing another means of reading data from the non-volatile memory according to the present invention. FIG. 3E is a schematic cross-sectional view of a non-volatile memory showing a means of erasing data from the non-volatile memory according to the present invention. FIG. 3F is a schematic cross-sectional view of a non-volatile memory showing another means of erasing data from the non-volatile memory according to the present invention.

As shown in FIG. 2, the memory cell array includes nine memory cells M11˜M33, a plurality of select gates SG1˜SG3, a plurality of word lines WL1˜WL3, and a plurality of bit lines BL1˜BL4.

Each of the memory cells M11˜M33 includes a select gate, a control gate and two charge storage layers, and two source/drain regions. Furthermore, every pair of adjacent memory cells uses a common control gate and a common source/drain region.

Each memory cell row includes three serially connected memory cells. For example, the memory cells M11˜M13 are serially connected together, the memory cells M21˜M23 are serially connected together, and the memory cells M31˜M33 are serially connected together.

The word lines WL1˜WL3 respectively connect to the control gates of the memory cells in the same rows. For example, the word line WL1 connects to the control gate of the memory cells M11˜M13; the word line WL2 connects to the control gate of the memory cells M21˜M23, and the word line WL3 connects to the control gate of the memory cells M31˜M33.

The select gate lines SG1˜SG3 respectively connect to the select gates of the memory cells in the same column. For example, the select gate line SG1 connects to the select gate of the memory cells M11˜M31; the select gate SG2 connects to the select gate of the memory cells M12˜M32, and the select gate line SG3 connects to the select gate of the memory cells M13˜M33.

An explanation of a method of operating a non-volatile memory according to one embodiment of the present invention is further provided. However, the method of operating the non-volatile memory is not limited as such. The following description uses the memory cell M22 as an example.

As shown in FIGS. 2 and 3A, to inject electrons into the charge storage layer A (the right bit) of the memory cell M22 in a programming operation, a voltage Vp1 is applied to the selected word line WL2 connected to the selected memory cell M22. The voltage Vp1 is about 8V, for example. A second voltage Vp2 is applied to the selected bit line BL3 on the charge storage layer A (the right bit) side next to the charge storage layer A (the right bit). The voltage Vp2 is about 5V, for example. A third voltage Vp3 is applied to the selected bit line BL2 on the charge storage layer B (the left bit) side next to the charge storage layer B (the left bit). The voltage Vp3 is about 0V, for example. A fourth voltage Vp4 is applied to the selected select gate line SG2. The voltage Vp4 is about 2V, for example. Through source-side injection (SSI) effect, electrons are injected into the charge storage layer A (the right bit) to program a right bit of data in the memory cell M22. In this operation, the voltage Vp4 is close to the threshold voltage of the select gate, the voltage Vp2 is greater than the voltage Vp3, and the voltage Vp1 is greater than the voltage Vp2 to facilitate the programming operation through source-side injection (SSI) process. Furthermore, a voltage Vp5, such as 0V or a negative voltage (about −1V), can be applied to other non-selected select gate lines SG1, SG3, and so forth. Consequently, the channel underneath the non-selected select gates is blocked.

In the aforementioned programming operation, the control gates in the non-volatile memory fill the trenches in the substrate. When the electrons move from the bit line BL2 toward the bit lines BL3, the electrons will be directly injected into the charge storage layer A (the right bit) on the sidewall of the trench after acceleration. Hence, higher injection efficiency can be obtained.

In FIGS. 2 and 3B, the process of injecting electrons into the charge storage layer B (the left bit) of the memory cell M22 and then programming a left bit of data in the memory cell M22 is explained. A first voltage Vp1 is applied to the selected word line WL2 which connects with the selected memory cell M22. The first voltage Vp1 is about 8V, for example. A second voltage Vp2 is applied to the selected bit line BL2 on the charge storage layer B (the left bit) side adjacent to the charge storage layer B (the left bit). The second voltage Vp2 is about 5V, for example. A third voltage Vp3 is applied to the selected bit line BL3 on the charge storage layer A (the right bit) side adjacent to the charge storage layer A (the right bit). The third voltage Vp3 is about 0V, for example. A fourth voltage Vp4 is applied to the selected select gate line SG2. The fourth voltage Vp4 is about 2V, for example. Through the source-side injection (SSI) effect, electrons are injected into the charge storage layer A (the right bit) to program a right bit of data in the memory cell M22. In this operation, the fourth voltage Vp4 is close to the threshold voltage of the select gate, the second voltage Vp2 is greater than the third voltage Vp3, and the first voltage Vp1 is greater than the second voltage Vp2 to facilitate the programming operation through source-side injection (SSI). Furthermore, a fifth voltage Vp5 can be applied to the other non-selected select gate lines SG1, SG3, and so forth. The fifth voltage Vp5 is, for example, 0V or a negative voltage (−1V) so that the channel underneath the non-selected select gates is blocked. Similarly, the control gates in the non-volatile memory fill the trenches in the substrate. When the electrons move from the bit line BL2 toward the bit lines BL3, the electrons will be directly injected into the charge storage layer B (the left bit) on the sidewall of the trench after acceleration. Hence, higher injection efficiency can be obtained.

As shown in FIGS. 2 and 3C, the process of reading data from the charge storage layer A (the right bit) of the memory cell M22 includes applying a first voltage Vr1 to the selected word line with connection to the selected memory cell M22. The first voltage Vr1 is about 5V-7V, for example. A second voltage Vr2 is applied to the selected bit line BL3 on the charge storage layer A (the right bit) side adjacent to the charge storage layer A (the right bit). The second voltage Vr2 is about 1.5V, for example. A third voltage Vr3 is applied to the selected bit line BL2 on the charge storage layer B (the left bit) side adjacent to the charge storage layer B (the left bit). The third voltage Vr3 is about 0V, for example. A fourth voltage Vr4 is applied to the selected select gate line SG2. The fourth voltage Vr4 is about 4V, for example. Hence, the right bit of data in the memory cell M22 can be read. In the operation, the second voltage Vr2 is greater than the third voltage Vr3, and the first voltage Vr1 should be greater than the threshold voltage of the memory cells without any electrons but smaller than the threshold voltage of the memory cells with electrons.

As shown in FIGS. 2 and 3D, the process of reading data from the charge storage layer B (the left bit) of the memory cell M22 includes applying a first voltage Vr1 to the selected word line with connection to the selected memory cells M22. The first voltage Vr1 is about 3V-7V, for example. A second voltage Vr2 is applied to the selected bit line BL3 on the charge storage layer B (the left bit) side adjacent to the charge storage layer B (the left bit). The second voltage Vr2 is about 1.5V, for example. A third voltage Vr3 is applied to the selected bit line BL2 on the charge storage layer A (the right bit) side adjacent to the charge storage layer A (the right bit). The third voltage Vr3 is about 0V, for example. A fourth voltage Vr4 is applied to the selected select gate line SG2. The fourth voltage Vr4 is about 4V, for example. Hence, the right bit of data in the memory cell M22 can be read. In the operation, the second voltage Vr2 is greater than the third voltage Vr3, and the first voltage Vr1 should be greater than the threshold voltage of the memory cells without any electrons but smaller than the threshold voltage of the memory cells with electrons.

In the aforementioned reading operation, the current flowing in a closed channel is weak while memory cells carry negative quantity of charges in the charge storage layer, and the current flowing in an turned on channel is strong while memory cells carry slightly positive quantity of charges in the charge storage layer. Accordingly, the strength of the current in the channel and the turn on/turnoff state of the channel can be used to determine whether the digital signal stored in the memory cell is a ‘1’ or a ‘0’.

As shown in FIGS. 2 and 3E, the process of erasing data from the memory cell includes applying a first voltage Ve1 to the selected word line and applying a second voltage Ve2 to the substrate. As a result, the select gate lines SG1˜SG3 are set in a floating state so that the electrons in the charge storage layers are channeled into the word lines to wipe out the data in the memory cells. The voltage differential between the first voltage Ve1 and the second voltage V2 will initiate the FN tunneling effect. The voltage differential between the first and the second voltage (Ve1 and Ve2) is about 12V-20V. For example, the first voltage Ve1 is about 15V and the second voltage Ve2 is about 0V, or the first voltage Ve1 is about 10V and the second voltage Ve2 is about −5V.

In the aforementioned embodiment, electrons removed via the word lines are used as an example. Obviously, the electrons can also be removed via the select gate lines. As shown in FIGS. 2 and 3F, the process of erasing data from the memory cell includes applying a first voltage Ve1 to the selected select gate line and applying a second voltage Ve2 to the substrate. As a result, the word lines WL1˜WL3 are set in a floating state so that the electrons in the charge storage layer are channeled into the select gate lines to wipe out the data in the memory cells. The voltage differential between the first voltage Ve1 and the second voltage Ve2 will trigger the FN tunneling effect. The voltage differential between the first and the second voltage (Ve1 and Ve2) is about 12V-20V. For example, the first voltage Ve1 is about 15V and the second voltage Ve2 is about 0V, or the first voltage Ve1 is about 10V and the second voltage Ve2 is about −5V. When electrons are removed via the select gate lines, a sharp corner is preferably set up in the area of the charge storage layer adjacent to the select gate structure. The sharp corner can speed up the operation of erasing data from the memory cells.

In the method of operating the non-volatile memory according to the present invention, the programming operation is carried out in a source-side injection (SSI) process, utilizing a single bit of data in a single memory cell as an unit. Additionally, the memory cell erasing operation is carried out by the FN tunneling effect. Therefore, the memory cell current can be reduced while the operating speed is increased thanks to the high efficiency of electron injection. As a result, overall current loss is minimized and the power consumption of the chip is significantly reduced.

Furthermore, the control gates in the non-volatile memory fill up the trenches in the substrate of the non-volatile memory. Thus, the accelerated electrons will be directly injected into the charge storage layer on the sidewall of the trench and higher injection efficiency can be obtained.

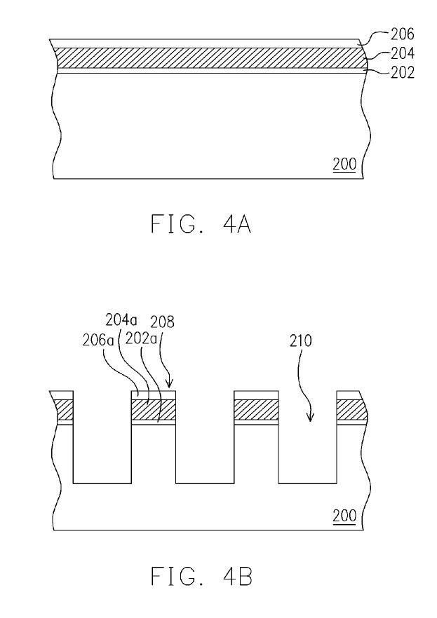

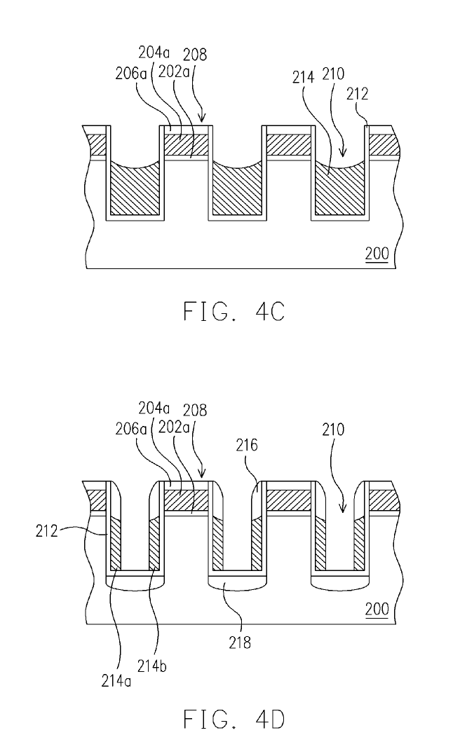

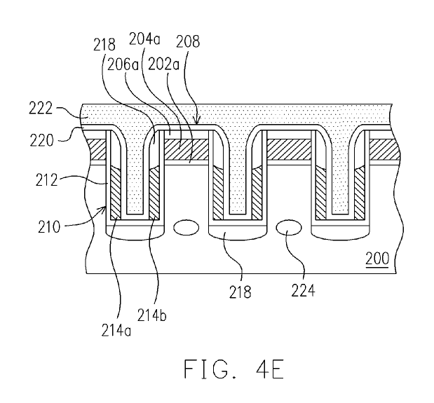

FIGS. 4A through 4E are schematic cross-sectional views showing the steps for fabricating a non-volatile memory according to one embodiment of the present invention. In fact, FIGS. 4A through 4E are cross-sectional views along line A-A′ in FIG. 1A, showing the process of fabricating the memory cells in a non-volatile memory.

First, as shown in FIG. 4A, a substrate 200 such as a silicon substrate is provided. Then, device isolation structures (not shown) are formed in the substrate 200. The device isolation structures are formed, for example, by performing a shallow trench isolation (STI) process. Thereafter, a dielectric layer 202, a conductive material layer 204 and a cap layer 206 are sequentially formed over the substrate 200. The dielectric layer 202 is a silicon oxide layer, for example, formed by performing a thermal oxidation process. The conductive material layer 204 is fabricated using doped polysilicon, for example. The conductive material layer 204 is formed, for example, by depositing undoped polysilicon in a chemical vapor deposition process and then performing an ion implantation on the undoped polysilicon layer. Alternatively, the conductive material layer 204 is formed, for example, by performing a chemical vapor deposition process with in-situ doping. The cap layer 206 is fabricated using silicon nitride and formed by performing a chemical vapor deposition process, for example.

As shown in FIG. 4B, the dielectric layer 202, the conductive material layer 204 and the cap layer 206 are patterned to form a plurality of select gate structures 208 on the substrate 200. Each select gate structure 208 includes a dielectric layer 202a, a conductive layer 204a, and a cap layer 206a, for example. The conductive layer 204a serves as a select gate and the dielectric layer 202a serves as a select gate dielectric layer. Thereafter, using the cap layer 206a as a mask, a portion of the substrate 200 is removed to form a plurality of trenches 210 in the substrate 200. The method of removing a portion of the substrate 200 includes performing a dry etching operation such as a reactive ion etching operation.

As shown in FIG. 4C, a tunneling dielectric layer 212 is formed over the surface of the trenches 210. The tunneling dielectric layer 212 is fabricated using silicon oxide and formed by performing a thermal oxidation process, for example. Because the tunneling dielectric layer 212 is formed in a thermal oxidation process, the conductive layer 204a will also be oxidized to form an oxide layer. Thereafter, a charge storage material layer 214 is formed in the trenches 210. The charge storage material layer 214 is fabricated using a conductive material such as doped polysilicon and formed, for example, by depositing undoped polysilicon material in a chemical vapor deposition process. And then an undoped polysilicon layer is formed. Thereafter, an ion implantation on the undoped polysilicon layer is performed and an etching back operation is carried out to remove a portion of the charge storage material layer 214 so that the top portion of the charge storage material layer 214 is below the surface of the substrate 200.

As shown in FIG. 4D, spacers 216 are formed on respective sidewalls of the trenches 210 to cover a portion of the upper surface of the charge storage material layer 214. The spacers 216 are fabricated using a material with an etching selectivity that differs from the charge storage material layer 214, for example. The method of forming the spacers 216 includes depositing insulating material to form an insulating material layer (not shown) and performing an anisotropic etching operation to remove a portion of the insulating material layer.

After that, using the cap layer 206a and the spacers 216 as an etching mask, a portion of the charge storage material layer 214 is again removed to form a first charge storage layer 214a and a second charge storage layer 214b on respective sidewalls of the trenches 210. The first charge storage layer 214a and the second charge storage layer 214b serve as floating gates, for example.

Then, source/drain regions 218 are formed in the substrate 200 at the bottom of the trenches 210. The method of forming the source/drain regions 218 includes performing an ion implantation process, for example.

As shown in FIG. 4E, an inter-gate dielectric layer 220 is formed over the substrate 200. The inter-gate dielectric layer 220 can be an oxide/nitride/oxide (ONO) composite stack layer, for example. The method of forming the inter-gate dielectric layer 220 includes, for example, sequentially depositing silicon oxide, silicon nitride and silicon oxide over the substrate 200 in a chemical vapor deposition process to form a composite layer including a silicon oxide layer, a silicon nitride layer and another silicon oxide layer. Obviously, the method of forming the inter-gate dielectric layer 220 may include forming a silicon oxide layer in a thermal oxidation process and performing a chemical vapor deposition process to form a silicon nitride layer and another silicon oxide layer thereafter. Furthermore, the inter-gate dielectric layer 220 can be a silicon oxide layer or an oxide/nitride composite layer, for example.

Thereafter, a plurality of conductive layers 222 are formed over the substrate 200. The conductive layers 222 completely fill the trenches 210 in the substrate 200. Furthermore, the conductive layers 222 are aligned in parallel to one another and extend in a direction that crosses over the direction of the conductive layer 204a (the select gate). The conductive layers 222 serve as word lines, for example. The conductive layers 222 (the word lines) are formed, for example, by depositing conductive material over the substrate, planarizing the conductive material layer in a chemical-mechanical polishing process or in an etching back process, and finally patterning the conductive material layer. As a result, a plurality of conductive material 222 are formed. The conductive layers 222 are fabricated using doped polysilicon, for example. The method of forming the conductive layers 222 includes depositing undoped polysilicon material in a chemical vapor deposition process and performing an ion implantation thereafter. Alternatively, the conductive layers 222 are formed by performing a chemical vapor deposition process with in-situ doping.

Thereafter, an anti-punch-through doped region 224 is formed in the substrate 200 between adjacent source/drain regions 218. The method of forming the anti punch-through-doped region 224 includes performing an ion implantation, for example. Since the subsequent process for producing a complete memory cell array should be familiar to those skilled in the fabrication technique, a detailed description is omitted here.

In the aforementioned embodiment, the first charge storage layer 214a and the second charge storage layer 214b are formed by removing a portion of the charge storage material layer 214,using the cap layer 206a and the spacers 216 as an etching mask after forming the spacers 216. Obviously, in the present invention, the first charge storage layer 214a and the second charge storage layer 214b can also be formed by directly patterning the charge storage material layer 214 in photolithographic and etching processes without forming the spacers 216.

Moreover, the charge storage material layer 214 in the aforementioned embodiment is fabricated using a conductive material (doped polysilicon). Obviously, the charge storage material layer 214 can be fabricated using a charge-trapping material (for example, silicon nitride). In this case, since the charge-trapping material has the characteristics of capturing electrons, the electrons injected into the charge storage material layer 214 will concentrate in a local region of the charge storage material layer 214. Therefore, there is no need to form the device isolation structures and to perform a special process to divide the charge storage material layer 214 into two blocks.

In the aforementioned embodiment of the present invention, the charge storage layers (the floating gates) and the control gates are formed within the trenches of the substrate. Hence, the dimension of each memory cell can be reduced and the level of integration of the devices can be raised. Furthermore, the charge storage layer (the two charge storage layers adjacent to the select gate structure) on respective sides of each trench can be used to store one bit of data. In other words, a single memory cell in the non-volatile memory of the present invention can hold two bits of data. Moreover, the channel length of the memory cells can be adjusted by controlling the depth of the trenches in the production process so that abnormal electrical punch-through in the memory cells can be avoided. In addition, relatively simple processes are used to fabricate the non-volatile memory in the present invention and the processes are particularly suitable for raising the level of integration of a memory cell array.

Although a structure with just three memory cells is used in the illustration of the embodiments, the number of memory cells which can be formed by the method of fabricating a non-volatile memory in the present invention has no restrictions. For example, a single word line can serially connect 32 to 64 memory cell structures together.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A non-volatile memory, comprising:
a substrate having at least two trenches therein;
a select gate disposed on the substrate between the two trenches; two charge storage layers disposed on respective sidewalls of the trenches next to the select gate;
two source/drain regions disposed in the substrate at the bottom of respective trenches; and
a control gate disposed on the substrate and filling the two trenches.

2. The non-volatile memory of claim 1, wherein the material constituting the two charge storage layers comprises doped polysilicon.

3. The non-volatile memory of claim 1, wherein the material constituting the two charge storage layers comprises silicon nitride.

4. The non-volatile memory of claim 1, wherein each charge storage layer has a sharp corner in the region next to the select gate.

5. The non-volatile memory of claim 1, wherein the material constituting the select gate comprises doped polysilicon.

6. The non-volatile memory of claim 1, further comprises a select gate dielectric layer disposed between the select gate and the substrate.

7. The non-volatile memory of claim 1, further comprises a tunneling dielectric layer disposed between each charge storage layer and the substrate.

8. The non-volatile memory of claim 1, further comprises an inter-gate dielectric layer disposed between each charge storage layer and the control gate.

9. A non-volatile memory, comprising:
a substrate having a plurality of trenches therein, wherein the trenches extend in a first direction; a plurality of select gates disposed on the substrate between every pair of adjacent trenches, wherein the select gates extend in the first direction;
a plurality of charge storage layers disposed on respective sidewalls of the trenches;
a plurality of bit lines respectively disposed in the substrate at the bottom of respective trenches; and
a plurality of word lines disposed on the substrate, aligned in parallel to one another and filling the respective trenches, wherein the word lines extend in a second direction, and the second direction and the first direction cross over each other.

10. The non-volatile memory of claim 9, wherein the material constituting the charge storage layers comprises doped polysilicon.

11. The non-volatile memory of claim 9, wherein the material constituting the charge storage layers comprises silicon nitride.

12. The non-volatile memory of claim 9, wherein the charge storage layers all have a sharp corner next to the select gates.

13. The non-volatile memory of claim 9, further comprises an anti-punch-through doped region disposed in the substrate between every pair of adjacent bit lines.

14. The non-volatile memory of claim 9, further comprises a select gate dielectric layer disposed between the select gates and the substrate.

15. The non-volatile memory of claim 9, further comprises a tunneling dielectric layer disposed between the charge storage layers and the substrate.

16. The non-volatile memory of claim 9, further comprises an inter-gate dielectric layer disposed between the charge storage layers and the word lines.

17. The non-volatile memory of claim 9, wherein the charge storage layers on respective sidewalls of the trenches are separated from one another.

18. A manufacturing method of a non-volatile memory, comprising:
providing a substrate;
forming a plurality of first conductive layers on the substrate, wherein the first conductive layers extend in a first direction;
removing a portion of the substrate using the first conductive layers as a mask to form a plurality of trenches in the substrate;
forming a first dielectric layer to cover the substrate;
forming a first charge storage layer and a second charge storage layer on respective sidewalls of the trenches;
forming a plurality of doped regions in the substrate at the bottom of the trenches;
forming a second dielectric layer over the substrate; and
forming a plurality of second conductive layers over the substrate, wherein the second conductive layers extend in a second direction and fill the trenches, and the second direction and the first direction cross over each other.

19. The method of claim 18, wherein the step of forming the first charge storage layer and the second charge storage layer on respective sidewalls of the trenches comprises:
depositing a charge storage material to fill the trenches;
performing a etching back process so that the top of the charge storage material layer is below the surface of the substrate;
forming a spacer on respective sidewalls of the trench to cover a portion of the charge storage material layer, and
removing a portion of the charge storage material layer by using the spacers and the first conductive layers as an etching mask to form the first charge storage layer and the second charge storage layer on the respective sidewalls of the trenches.

20. The method of claim 18, wherein the step of forming the first charge storage layer and the second charge storage layer on respective sidewalls of the trenches comprises:
depositing a charge storage material to fill the trenches, and
patterning the charge storage material layer to form the first charge storage layer and the second charge storage layer on respective sidewalls of the trenches.

21. The method of claim 18, wherein the step of forming the first conductive layers on the substrate comprises:
forming a gate dielectric layer over the substrate;
forming a conductive material layer over the gate dielectric layer;
forming a cap layer over the conductive material layer, and
patterning the cap layer, the conductive material layer and the gate dielectric layer.

22. The method of claim 18, wherein the material constituting the first charge storage layer and the second charge storage layer comprises doped polysilicon.

23. The method of claim 18, wherein the material constituting the first charge storage layer and the second charge storage layer comprises silicon nitride.

24. A method of operating a non-volatile memory for a memory cell array, the memory cell array comprising: a plurality of select gates disposed on a substrate with a trench in the substrate between every pair of adjacent select gates, a plurality of charge storage layer disposed on respective sidewalls of the trenches next to the select gates, a plurality of control gates filling the trenches between two adjacent select gates, a plurality of word lines aligned in parallel to one another in the row direction to connect the control gates in the same row, a plurality of select gate lines aligned in parallel to one another in the column direction to connect the select gates in the same column, a plurality of bit lines aligned in parallel to one another in the column direction and disposed in the substrate underneath the trenches, wherein a pair of adjacent control gates in the row direction, a select gate between the two adjacent control gates, and a pair of charge storage layers adjacent to the select gate together form a memory cell; for each memory cell, the charge storage layer on a first side of the select gate stores a first bit of data, and the charge storage layer on a second side of the select gate stores a second bit of data; the method of performing a programming operation comprising:
applying a first voltage to a selected word line connected to a selected memory cell;
applying a second voltage to a first selected bit line on the first bit side of the selected memory cell;
applying a third voltage to a second selected bit line on the second bit side of the selected memory cell; and
applying a fourth voltage to a selected select gate line of the memory cell, wherein the fourth voltage is close to the threshold voltage of the selected gate, the second voltage is greater than the third voltage, and the first voltage is greater than the second voltage so that the first bit of the selected memory cell is programmed through source-side injection effect.

25. The operating method of claim 24, wherein the first voltage is about 8V, the second voltage is about 5V, the third voltage is about 0V, and the fourth voltage is about 2V.

26. The operating method of claim 24, wherein the process of programming data into the memory cell further comprises:
applying the first voltage to the selected word line connected to the selected memory cell;
applying the third voltage to the first selected bit line on the first bit side of the selected memory cell;
applying the second voltage to the second selected bit line on the second bit side of the selected memory cell; and
applying the fourth voltage to the selected select gate line of the selected memory cell, wherein the fourth voltage is close to the threshold voltage of the select gate, the second voltage is greater than the third voltage, and the first voltage is greater than the second voltage so that the second bit of the selected memory cell is programmed through source-side injection effect.

27. The operating method of claim 26, wherein the first voltage is about 8V, the second voltage is about 5V, the third voltage is about 0V, and the fourth voltage is about 2V.

28. The operating method of claim 24, wherein the process of performing the programming further comprises applying a fifth voltage to the non-selected select gate lines so that the channels underneath the non-selected select gates are blocked.

29. The operating method of claim 28, wherein the fifth voltage is about −1V.

30. The operating method of claim 24, wherein the method further comprises performing an erasing operation by applying a sixth voltage to the word lines and applying a seventh voltage to the substrate so that the electrons stored in the charge storage layers are channeled into the word lines and the Fowler-Nordheim (FN) effect is triggered through a voltage differential between the sixth voltage and the seventh voltage.

31. The operating method of claim 30, wherein the voltage differential is about from 12V to 20V.

32. The operating method of claim 30, wherein the sixth voltage is about 15V and the seventh voltage is about 0V.

33. The operating method of claim 30, wherein the sixth voltage is about 10V and the seventh voltage is about −5V.

34. The operating method of claim 24, wherein the method further comprises performing an erasing operation by applying an eighth voltage to the select gate lines and applying a ninth voltage to the substrate so that the electrons stored in the charge storage layers are channeled into the select gate lines and the Fowler-Nordheim (FN) effect is triggered through a voltage differential between the eighth voltage and the ninth voltage.

35. The operating method of claim 34, wherein the voltage differential is about 12V-20V.

36. The operating method of claim 34, wherein the eighth voltage is about 15V and the ninth voltage is about 0V.

37. The operating method of claim 24, wherein the method further comprises performing a reading operation by applying a tenth voltage to a selected word line connected to a selected memory cell, applying an eleventh voltage to the first selected bit line on the first bit side of the selected memory cell, applying a twelfth voltage to the second selected bit line on the second bit side of the selected memory cell, and applying a thirteenth voltage to the selected select gate line of the selected memory to read a first bit of data; the eleventh voltage is greater than the twelfth voltage, and the tenth voltage is greater than the threshold voltage of the memory cells without any electrons but smaller than the threshold voltage of the memory cells with electrons.

38. The operating method of claim 37, wherein the tenth voltage is about 5V-7V, the eleventh voltage is about 1.5V, the twelfth voltage is about 0V, and the thirteenth voltage is about 4V.

39. The operating method of claim 24, wherein the method further comprises performing a reading operation by applying a tenth voltage to the selected word line connected to the selected memory cell, applying a twelfth voltage to the first selected bit line on the first bit side of the selected memory cell, applying an eleventh voltage to the second selected bit line on the second bit side of the selected memory cell, and applying a thirteenth voltage to the selected select gate line of the selected memory to read a second bit of data; the eleventh voltage is greater than the twelfth voltage, and the tenth voltage is greater than the threshold voltage of the memory cells without any electrons but smaller than the threshold voltage of the memory cells with electrons.

40. The operating method of claim 39, wherein the tenth voltage is about 5V-7V, the eleventh voltage is about 1.5V, the twelfth voltage is about 0V, and the thirteenth voltage is about 4V.
